(19) United States
(12) Patent Application Publication
(10) Pub. No.: US 2012/0105259 A1
(43) Pub. Date: May 3, 2012

(54) PORTABLE ELECTRONIC DEVICE

(75) Inventor: JIAN-HUI LI, Shenzhen (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/045,630

(22) Filed: Mar. 11, 2011

(30) Foreign Application Priority Data
Oct. 29, 2010 (CN) 201010524884.2

(51) Int. Cl. H03K 17/94

(52) U.S. Cl. 341/22

(57) ABSTRACT

A portable electronic device includes a main body, a keyboard assembly located behind the main body; and an earphone. The main body defines a receiving groove, the earphone is received in the receiving groove and can be partially exposed out of the main body. The keyboard assembly is rotatably connected to one end of the main body and can be rotated flush with the main body.

### BACKGROUND

1. Technical Field

The present disclosure generally relates to portable electronic devices.

2. Description of Related Art

Many portable electronic devices such as mobile phones utilize a detachable earphone, which can be inconvenient to transport and easily lost. Generally, the portable electronic device includes a keyboard monotonous in appearance, and does not satisfy individuality demands of consumers.

Therefore, there is room for improvement within the art.

### BRIEF DESCRIPTION OF THE DRAWINGS

Many aspects of the exemplary portable electronic device can be better understood with reference to the following drawings. The components in the drawings are not necessarily to scale, the emphasis instead being placed upon clearly illustrating the portable electronic device. Moreover, in the drawings, like reference numerals designate corresponding parts out the several views.

FIG. 1 is a schematic view of a portable electronic device, according to an exemplary embodiment of the present disclosure.

FIG. 2 is an exploded view of the portable electronic device shown in FIG. 1.

FIG. 3 is similar to FIG. 2, shown from another angle.

FIG. 4 is an enlarged view of part shown in FIG. 2.

FIG. 5 is similar to FIG. 1, shown from another angle.

FIG. 6 is a schematic view of the portable electronic device shown in FIG. 1 in one usage state.

FIG. 7 is a schematic view of the portable electronic device shown in FIG. 1 in another usage state.

### DETAILED DESCRIPTION

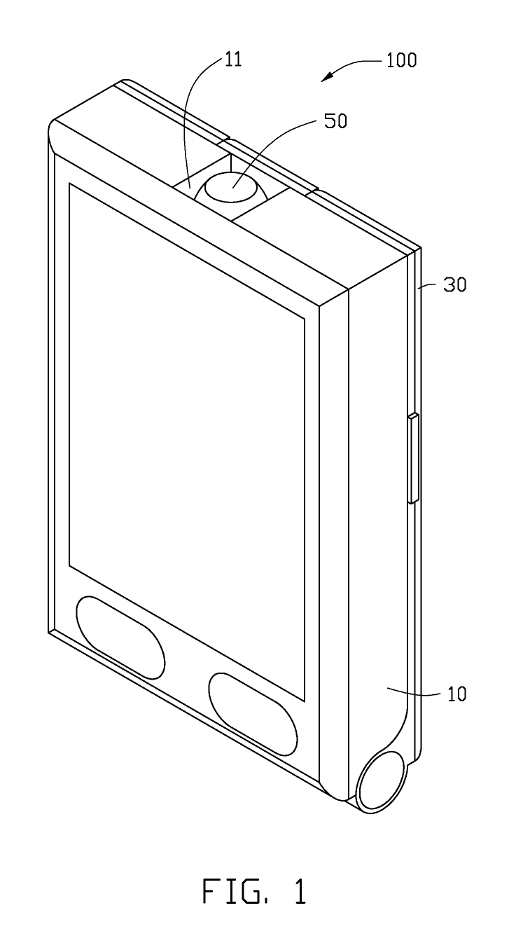

Referring to FIG. 1, an exemplary embodiment provides a portable electronic device 100 including a main body 10, a keyboard assembly 30, and an earphone 50. The keyboard assembly 30 is rotatably connected to one end of the main body 10 and can be located behind the main body 10. A receiving groove 11 is defined in the main body 10. The earphone 50 is received in the receiving groove 11.

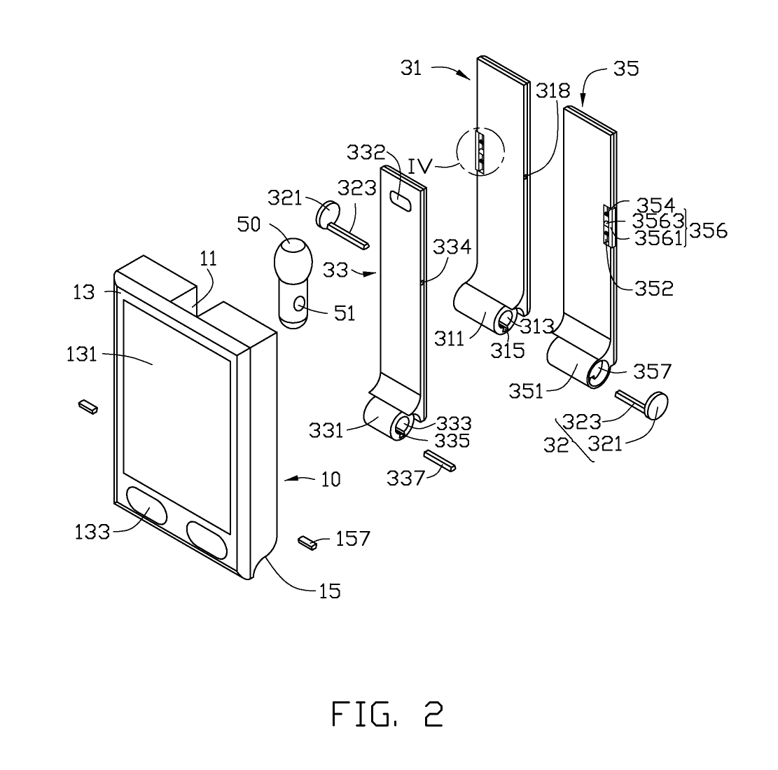

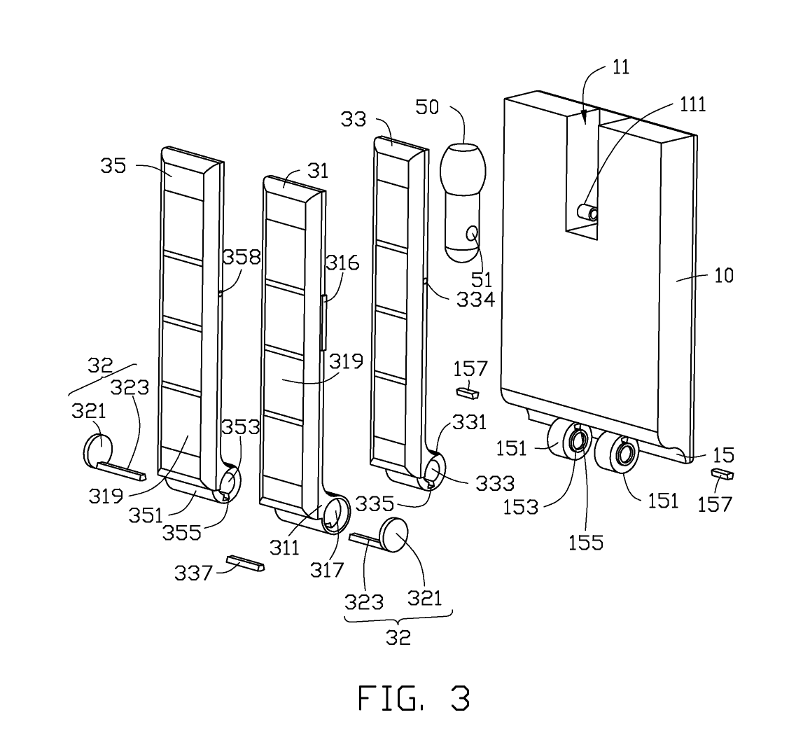

Referring to FIG. 2 and FIG. 3, the main body 10 includes an upper surface 13 on which a display screen 131 and two function keys 133 are located. Two shaft portions 111 are oppositely located in the receiving groove 11. The earphone 50 defines a shaft hole 51 corresponding to the two shaft portions 111. The end of the main body 10 away from the receiving groove 11 defines a recess 15. Two cylindrical engagement portions 151 spaced from each other are located in the recess 15. Two annular protrusions 153 are oppositely located on each engagement portion 151. Each engagement portion 151 defines a guide hole 155 adjacent to the protrusion 153. A block 157 is movably received in each guide hole 155.

The keyboard assembly 30 includes a first sub-keyboard 31, a second sub-keyboard 33 and a third sub-keyboard 35. The first sub-keyboard 31 and the third sub-keyboard 35 are located at opposite sides of the second sub-keyboard 33. The first sub-keyboard 31, the second sub-keyboard 33 and the third sub-keyboard 35 are rotatably connected to the main body 10 respectively. Pluralities of keys 319 are located on the first sub-keyboard 31, the second sub-keyboard 33, and the third sub-keyboard 35.

The first sub-keyboard 31 includes a rotation portion 311. The rotation portion 311 defines a first receiving depression 313 and a second receiving depression 317. An inner surface of the first receiving depression 313 defines a sliding slot 315 in communication with the second receiving depression 317. A plug 32 including a flange portion 321 and a rod portion 323 is movably received in the rotation portion 311. The flange portion 321 is movably received in the second receiving depression 317, and the rod portion 323 is movably received in the sliding slot 315. When the flange portion 321 resists a bottom surface of the second receiving depression 317, the rod portion 323 is partially exposed from the sliding slot 315.

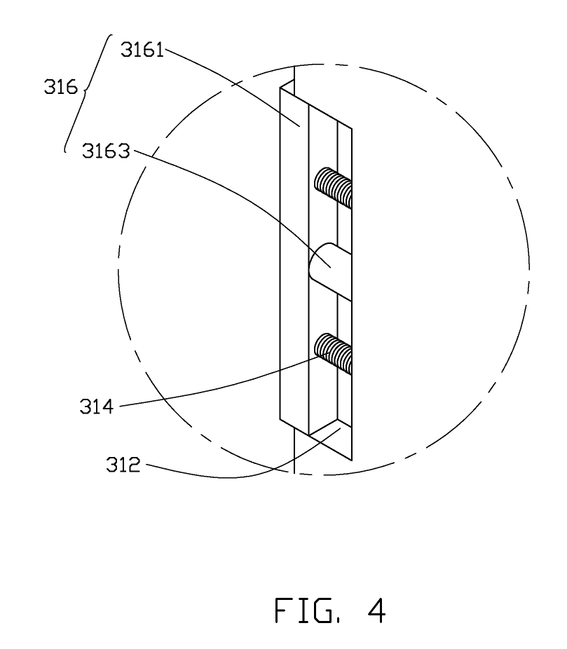

Referring to FIG. 2 and FIG. 4, a sidewall of the first sub-keyboard 31 defines a notch 312. Two springs 314 parallel to each other are located in the notch 312. An opposite sidewall of the first sub-keyboard 31 defines a through hole 318 in communication with the notch 312. One end of the through hole 318 is located between the two springs 314. A T-shaped lever 316 including an end portion 3161 and a stick portion 3163 perpendicular to the end portion 3161 is movably received in the notch 312. The end portion 3161 is securely connected to the two springs 314. The stick portion 3163 is movably received in the through hole 318. When the end portion 3161 is pressed toward the through hole 318, the stick portion 3163 is partially exposed out of the through hole 318.

Referring to FIG. 2 and FIG. 3, the second sub-keyboard 33 includes a connection portion 331. The connection portion 331 defines a connection hole 333, an inner surface of the connection hole 333 defines a sliding groove 335. A sliding pin 337 is slidably received in the sliding groove 335. A microphone 332 is located on one end of the second sub-keyboard 33 oriented away from the connection portion 331. The second sub-keyboard 33 includes two opposite side surfaces (not labeled), and each side surface defines an aperture 334 corresponding to the through hole 318.

The third sub-keyboard 35 includes a rotation portion 351. The rotation portion 351 defines a first receiving depression 353 and a second receiving depression 357. An inner surface of the first receiving depression 353 defines a sliding slot 355 in communication with the second receiving depression 357. A plug 32 including a flange portion 321 and a rod portion 323 is movably received in the rotation portion 351. The flange portion 321 is movably received in the second receiving depression 357, and the rod portion 323 is movably received in the sliding slot 355. When the flange portion 321 resists a bottom surface of the second receiving depression 357, the rod portion 323 is partially exposed out of the sliding slot 355.

A sidewall of the third sub-keyboard 35 defines a notch 352. Two springs 354 parallel to each other are located in the notch 352. An opposite sidewall of the third sub-keyboard 35 defines a through hole 358 in communication with the notch 352. One end of the through hole 358 is located between the two springs 354. A T-shaped lever 356 including an end portion 3561 and a stick portion 3563 perpendicular to the end portion 3561 is movably received in the notch 352. The end portion 3561 is securely connected to the two springs 354. The stick portion 3563 is movably received in the through hole 358. When the end portion 3561 is pressed toward the through hole 358, the stick portion 3563 is partially exposed out of the through hole 358.

Assembly of the portable electronic device 100 may be as follows.

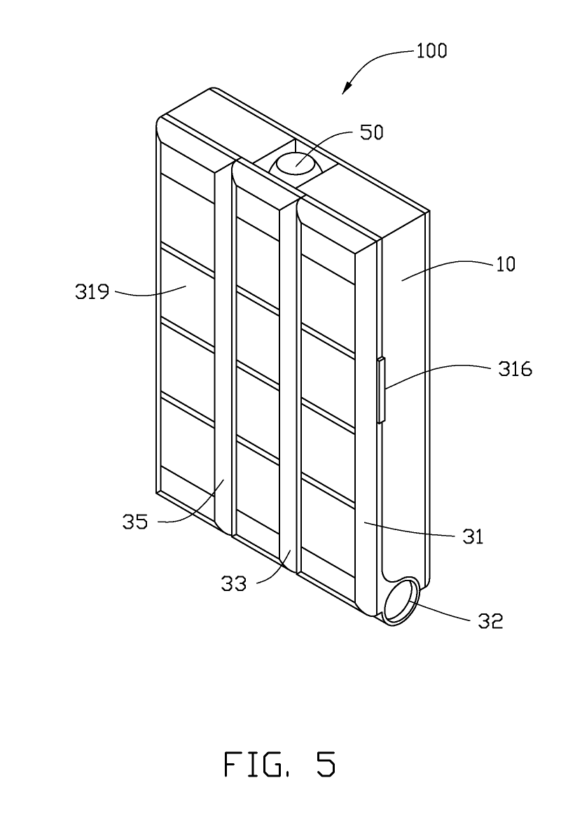

The two shaft portions 111 are rotatably received in the shaft hole 51. The connection portion 331 is located between the two engagement portions 151, and one protrusion 153 of each engagement portion 151 is rotatably received in the connection hole 333. The rotation portion 311 is located at a side of one engagement portion 151, the other protrusion 153 of which is rotatably received in the first receiving depression 313. The rotation portion 351 is located at a side of the other engagement portion 151, the other protrusion 153 of which is rotatably received in the first receiving depression 353. The assembled portable electronic device 100 is shown in FIG. 5.

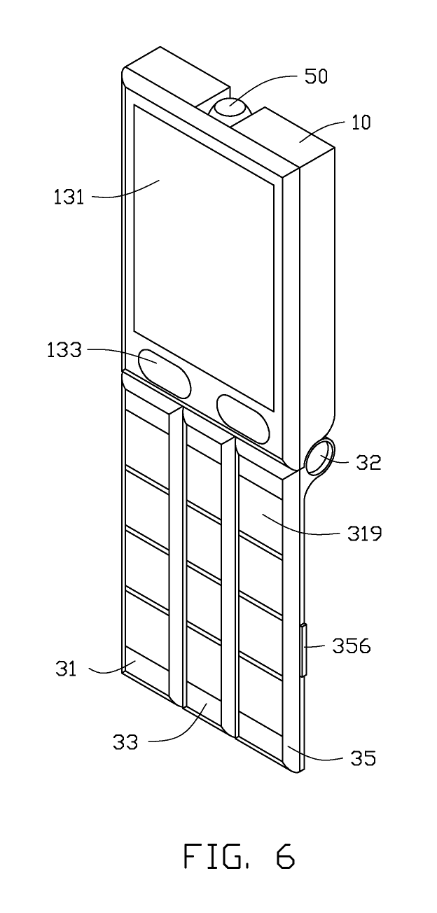

Also referring to FIG. 6, when the keyboard assembly 30 is needed, the levers 316, 356 are pressed toward the second sub-keyboard 33 until the stick portions 3163, 3563 are partially received in the apertures 334. Continued pressure on the levers 316, 356, allows for rotation of the keyboard assembly 30 until the keys 319 are flush with the display screen 131, and the sliding slots 315, 355, the sliding groove 335, and the two guide holes 155 are aligned. The plug 32 received in the rotation portion 311 is pressed toward the third sub-keyboard 35 until the rod portion 323 is partially received in the guide hole 155 adjacent to the rotation portion 311. According to the slide of the plug 32, the block 157 received in the guide hole 155 adjacent to the rotation portion 311 is partially received in the sliding groove 335; the sliding pin 337 is partially received in the guide hole 155 adjacent to the rotation portion 351; and the block 157 received in the guide hole 155 adjacent to the rotation portion 351 is partially received in the sliding slots 355.

When there keyboard assembly 30 is not needed, the plug 32 received in the rotation portion 351 is pressed toward the first sub-keyboard 31 until the two blocks 157, the sliding pin 337 and the plug 32 received in the rotation portion 311 return to original locations before allowing rotation of the keyboard assembly 30. The keyboard assembly 30 is then rotated to the rear of the main body 10 as shown in FIG. 5.

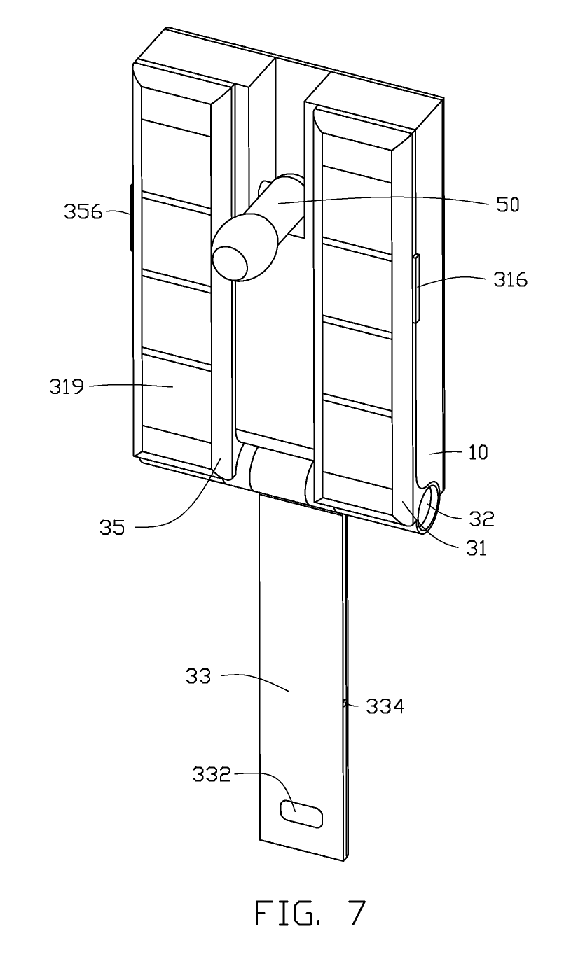

Referring to FIG. 7, when the earphone 50 is needed, the second sub-keyboard 33 is rotated until the keys 319 thereof are flush with the display screen 131. The earphone 50 is rotated until perpendicular to the main body 10. The earphone 50 can be used and the portable electronic device 100 is fixed without holding.

As detailed, the earphone 50 is received in the main body 10, easily transported and not easily lost. The keyboard assembly 30 can be rotated relative to the main body 10 as needed.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A portable electronic device, comprising:
a main body;
a keyboard assembly located behind the main body; and
an earphone;
wherein the main body defines a receiving groove, the earphone is received in the receiving groove and can be partially exposed out of the main body; the keyboard assembly is rotatably connected to one end of the main body and can be rotated flush with the main body.

2. The portable electronic device as claimed in claim 1, wherein the earphone is rotatably received in the receiving groove and can be rotated partially out of the receiving groove.

3. The portable electronic device as claimed in claim 2, wherein the keyboard assembly comprises a first sub-keyboard, a second sub-keyboard, and a third sub-keyboard, the first sub-keyboard, the second sub-keyboard, and the third sub-keyboard are rotatably connected to the main body respectively.

4. The portable electronic device as claimed in claim 3, wherein a sidewall of the first sub-keyboard defines a notch, two springs parallel to each other are located in the notch; a lever connected to the two springs is movably received in the notch.

5. The portable electronic device as claimed in claim 4, wherein an opposite sidewall of the first sub-keyboard defines a through hole in communication with the notch.

6. The portable electronic device as claimed in claim 5, wherein the lever comprises an end portion and a stick portion perpendicular to the end portion, the end portion is securely connected to the two springs, the stick portion is movably received in the through hole.

7. The portable electronic device as claimed in claim 6, wherein the second sub-keyboard comprises two opposite side surfaces, each side surface defines an aperture corresponding to the through hole; when the end portion is pressed toward the through hole, the stick portion is partially received in an aperture adjacent to the through hole.

8. The portable electronic device as claimed in claim 7, wherein a sidewall of the third sub-keyboard defines a notch, two springs parallel to each other are located in the notch of the third sub-keyboard; a lever connected to the two springs is movably received in the notch of the third sub-keyboard.

9. The portable electronic device as claimed in claim 8, wherein an opposite sidewall of the third sub-keyboard defines a through hole in communication with the notch of the third sub-keyboard.

10. The portable electronic device as claimed in claim 3, wherein two engagement portions spaced from each other are located on one end of the main body oriented away from the receiving groove.

11. The portable electronic device as claimed in claim 10, wherein each engagement portion defines a guide hole, a block is movably received in each guide hole.

12. The portable electronic device as claimed in claim 11, wherein the first sub-keyboard comprises a rotation portion rotatably connected to one engagement portion; the third sub-keyboard comprises a rotation portion rotatably connected to the other engagement portion; the second sub-keyboard comprises a connection portion rotatably connected to the two engagement portions.

13. The portable electronic device as claimed in claim 12, wherein the rotation portion defines a first receiving depression and a second receiving depression, an inner surface of the first receiving depression defines a sliding slot in communication with the second receiving depression.

14. The portable electronic device as claimed in claim 13, wherein a plug including a flange portion and a rod portion is movably received in the rotation portion, the flange portion is movably received in the second receiving depression, and the rod portion is movably received in the sliding slot.

15. The portable electronic device as claimed in claim 14, wherein when the flange portion resists a bottom surface of the second receiving depression, the rod portion is partially exposed out of the sliding slot.

16. The portable electronic device as claimed in claim 15, wherein the connection portion defines a connection hole, an inner surface of the connection hole defines a sliding groove; a sliding pin is slidably received in the sliding groove.

17. The portable electronic device as claimed in claim 16, wherein when the keyboard assembly is flush with the main body, the sliding slots, the sliding groove, and the guide holes are aligned in a line.

18. A portable electronic device, comprising:
a main body;
a keyboard assembly; and
an earphone;
wherein the main body defines a receiving groove, the earphone is received in the receiving groove; the keyboard assembly located behind the main body partially covers the receiving groove; the keyboard assembly is rotatably connected to one end of the main body and can be rotated flush with the main body.

19. The portable electronic device as claimed in claim 18, wherein the earphone is rotatably received in the receiving groove and can be partially exposed out of the receiving groove.

20. The portable electronic device as claimed in claim 19, wherein the keyboard assembly comprises a first sub-keyboard, a second sub-keyboard, and a third sub-keyboard, the first sub-keyboard, the second sub-keyboard, and the third sub-keyboard are rotatably connected to the main body respectively.
